(19) United States
(12) Patent Application Publication
(10) Pub. No.: US 2007/0022941 A1
(43) Pub. Date: Feb. 1, 2007

(54) Method of forming a layer and method of manufacturing a semiconductor device using the same

(76) Inventors: Jae-Young Park, Yongin-si (KR); Young-Jin Kim, Seongnam-si (KR); Yong-Woo Hyung, Yongin-si (KR); Seok-Woo Nam, Yongin-si (KR); Kyoung-Seok Kim, Seoul (KR); Wook-Yeol Yi, Dong-gu (KR); Hun-Hyeoung Leam, Yongin-si (KR); Kong-Soo Lee, Hwaseong-si (KR); Ko-Eun Lee, Suwon-si (KR)

Correspondence Address: HARNESS, DICKEY & PIERCE, P.L.C., P.O. BOX 8910, RESTON, VA, 20195, US

(21) Appl. No.: 11/494,566

(22) Filed: Jul. 28, 2006

(30) Foreign Application Priority Data
Jul. 29, 2005 (KR) 2005-69355

(51) Int. Cl. C30B 15/14

(52) U.S. Cl. 117/3

(57) ABSTRACT

In a method of forming a layer having a lower electrical resistance and a method of manufacturing a semiconductor device, a first layer may be formed on a single crystalline substrate using amorphous silicon doped with impurities. A heat treatment may be performed on the single crystalline substrate at a temperature of about 550° C. to about 600° C. to convert the first layer into a second layer including a single crystalline silicon film transformed from a lower portion of the first layer contacting the single crystalline substrate and a polysilicon film transformed from an upper portion of the first layer. The layer may be formed at a relatively low temperature by a selective epitaxial growth process, and thus degradation or damage to a semiconductor device, which may be generated in a high temperature process, may be reduced.

### PRIORITY STATEMENT

This application claims priority under 35 USC. §119 to Korean Patent Application No. 10-2005-69355 filed on Jul. 29 2005, the contents of which are herein incorporated by reference in their entirety.

### BACKGROUND OF THE INVENTION

1. Field of the Invention

Example embodiments of the present invention relate to a method of forming a layer and a method of manufacturing a semiconductor device using the same. Example embodiments relate to a method of manufacturing a semiconductor device including a pad for electrically connecting a capacitor or a bit line to a source/drain region of a semiconductor substrate.

2. Description of the Related Art

As semiconductor devices have become more integrated and operation speeds of semiconductor devices have become faster, demand for forming finer patterns has increased. Accordingly, a width of a wiring and a distance between wirings have been remarkably reduced. Forming a pad may be very difficult because the pad connecting isolated elements on a semiconductor substrate by using a highly conductive layer has become finer.

As a size of the pad decreases, a contact hole aspect ratio may increase and a width of the contact hole may become narrower. Thus, a thickness of a native oxide layer frequently formed on a bottom portion of the contact hole may increase. When the native oxide layer has a relatively large thickness, electrical resistance of the pad may greatly increase.

When the electrical resistance of the pad increases, current drive capacity of the semiconductor device may be reduced and thus operation speed of the semiconductor device may also be deteriorated. Furthermore, a failure rate of refresh operation of the semiconductor device may increase.

Therefore, an additional process for removing the native oxide layer frequently formed on a substrate may be disadvantageously performed. However, the native oxide layer may be formed again by reoxidizing portions of the substrate during the subsequent high temperature process.

In order to prevent the native oxide layer from being formed, the pad may be conventionally formed by a selective epitaxial growth (SEG) process. However, the SEG process may damage semiconductor elements disposed on the substrate because the SEG process may be performed at a higher temperature above about 800° C. Thus, this process may deteriorate electrical characteristics of the semiconductor elements.

A solid phase epitaxial (SPE) growth process, which may be performed at a relatively lower temperature, has been adopted in order to alleviate the above-mentioned problems caused by performing the SEG process at a higher temperature.

A method of forming a pad by the SPE growth process is disclosed by the conventional art. According to this conventional method, an amorphous silicon layer undoped with impurities may be formed to fill up an opening exposing a source/drain region of a single crystalline silicon substrate, and then a heat treatment process may be performed on the amorphous silicon layer. While performing the heat treatment process, a lower portion of the amorphous silicon layer making contact with the single crystalline silicon substrate may be converted into a single crystalline silicon layer and an upper portion of the amorphous silicon layer may be changed into a polysilicon layer. Thus, the pad including the single crystalline silicon layer and the polysilicon layer may be formed.

Electric currents can flow through the single crystalline silicon layer and the polysilicon layer only when the single crystalline silicon layer and the polysilicon layer of the pad have a concentration of impurities above a certain level. The pad may then electrically connect semiconductor elements to one another on the single crystalline silicon substrate. However, the concentration of the impurities in the pad formed by the SPE growth process may be so low that electric currents cannot flow through the pad. For example, the single crystalline silicon layer and the polysilicon layer may be formed using amorphous silicon undoped with impurities, and the impurities included in an impurity region of the single crystalline silicon substrate may be diffused into the single crystalline silicon layer and the polysilicon layer. Thus, the concentration of impurities in the pad including the single crystalline silicon layer and the polysilicon layer may be very low.

An example method to increase a concentration of impurities in a pad is disclosed by the conventional art. According to this conventional method, an amorphous silicon layer doped with phosphorus (P) at a lower concentration may be formed to fill up an opening exposing a source/drain region of a semiconductor substrate, and then a polycrystalline silicon layer doped with phosphorus at a higher concentration may be formed on the amorphous silicon layer. When a heat treatment process is performed on the semiconductor substrate, a pad including a polysilicon layer doped with phosphorus and a single crystalline silicon layer doped with phosphorus on the polysilicon layer may be formed on the semiconductor substrate.

Semiconductor elements formed on the semiconductor substrate may be deteriorated because the polycrystalline silicon layer doped with phosphorus at a higher concentration may be formed at a higher temperature of about 580° C. to about 650° C.

### SUMMARY OF THE INVENTION

Example embodiments of the present invention relate to a method of forming a layer and a method of manufacturing a semiconductor device using the same. Example embodiments relate to a method of manufacturing a semiconductor device including a pad for electrically connecting a capacitor or a bit line to a source/drain region of a semiconductor substrate. Example embodiments of the present invention provide a method of forming a layer having a lower electrical resistance at a lower temperature and provide a method of manufacturing a semiconductor device using the method of forming the layer.

According to an example embodiment of the present invention, there is provided a method of forming a layer, wherein, a first layer may be formed on a single crystalline substrate using amorphous silicon doped with impurities. A heat treatment process may be performed on the single crystalline substrate to convert the first layer into a second layer. The second layer may include a single crystalline silicon film transformed from a lower portion of the first layer making contact with the single crystalline substrate, and a polysilicon film transformed from an upper portion of the first layer.

According to example embodiments of the present invention, the single crystalline substrate may include single crystalline silicon or single crystalline silicon germanium.

According to example embodiments of the present invention, the heat treatment process may be performed at a temperature of about 550° C. to about 600° C. under a nitrogen gas atmosphere.

According to example embodiments of the present invention, a native oxide layer may be removed from the single crystalline substrate.

According to other example embodiments of the present invention, there is provided a method of forming a layer, wherein a first layer may be formed on a single crystalline substrate using amorphous silicon undoped with impurities. A second layer may be formed on the first layer using amorphous silicon doped with impurities. A heat treatment process may be performed to form a third layer including a single crystalline silicon film transformed from the first layer and a polysilicon film transformed from the second layer.

According to example embodiments of the present invention, the first and the second layers may be formed by an in-situ process using substantially the same chamber.

According to the disclosed method of forming a layer, the layer may have a stacked structure in which single crystalline silicon film doped with impurities and a polysilicon film doped with impurities, and the layer may be formed at a temperature of about 550 to about 600° C. lower than that of a layer formed by a SEG process. Because amorphous silicon doped with impurities may be used, while forming the layer, concentration of the impurities in the layer is higher than that of the conventional layer. Thus, electrical resistance of the layer may be reduced.

According to still other example embodiments of the present invention, there is provided a method of manufacturing a semiconductor device, wherein a gate pattern may be formed on a single crystalline substrate. An impurity region may be formed at an upper portion of the single crystalline substrate adjacent to the gate pattern. An insulation layer may be formed on the single crystalline substrate to cover the gate pattern. The insulation layer may include an opening exposing the impurity region. A preliminary conductive layer may be formed on the impurity region using amorphous silicon doped with impurities to fill up the opening. A heat treatment process may be performed on the single crystalline substrate to convert the preliminary conductive layer into a conductive layer including a single crystalline silicon film doped with impurities and a polysilicon film doped with impurities. The single crystalline silicon film may be transformed from a lower portion of the preliminary conductive layer making contact with the single crystalline substrate, and the polysilicon film may be transformed from an upper portion of the preliminary conductive layer.

According to an example embodiment of the present invention, a native oxide layer may be removed from the impurity region by a cleaning process after forming the impurity region.

According to an example embodiment of the present invention, the conductive layer may be partially removed until the insulation layer is exposed to form a pad on the single crystalline substrate.

According to other embodiments of the present invention, there is provided a method of manufacturing a semiconductor device, wherein a gate pattern may be formed on a single crystalline substrate. An impurity region may be formed at an upper portion of the single crystalline substrate adjacent to the gate pattern. An insulation layer may be formed on the single crystalline substrate to cover the gate pattern. The insulation layer may include an opening exposing the impurity region. A first preliminary conductive layer may be formed on the impurity region using amorphous silicon undoped with impurities. A second preliminary conductive layer may be formed on the first preliminary conductive layer using amorphous silicon doped with impurities to fill up the opening. A heat treatment process may be performed on the single crystalline substrate to convert the first and the second preliminary conductive layers into a conductive layer including a single crystalline silicon film doped with impurities and a polysilicon film doped with impurities. The single crystalline silicon film may be transformed from the first preliminary conductive layer, and the polysilicon film is transformed from the second preliminary conductive layer.

According to example embodiments of the present invention, a pad may have a multi-layered structure including a single crystalline silicon film doped with impurities and a polysilicon film doped with impurities on the single crystalline silicon film. Damages to lower structures formed on a semiconductor substrate may be diminished because the pad may be formed at a lower temperature of about 550° C. to about 600° C. In addition, the pad may be formed using amorphous silicon doped with impurities, and the pad having a higher concentration of impurities may be formed. Thus, the pad may have a reduced electrical resistance, and a. semiconductor device including the pad may have an improved operation speed and a reduced refresh failure.

### BRIEF DESCRIPTION OF THE DRAWINGS

Example embodiments of the present invention will be more clearly understood from the following brief description taken in conjunction with the accompanying drawings. FIGS. 1-17 represent non-limiting, example embodiments of the present invention herein.

FIGS. 1 to 4 are cross-sectional views illustrating a method of forming a layer in accordance with example embodiments of the present invention;

FIGS. 5 to 7 are cross-sectional views illustrating a method of forming a layer in accordance with other example embodiments of the present invention;

FIGS. 8 to 14 are cross-sectional views illustrating a method of manufacturing a semiconductor device in accordance with example embodiments of the present invention; and

FIGS. 15 to 17 are cross-sectional views illustrating a method of manufacturing a semiconductor device in accordance with other example embodiments of the present invention.

### DESCRIPTION OF EXAMPLE EMBODIMENTS

Example embodiments of the present invention are described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments of the present invention relate to a method of forming a layer and a method of manufacturing a semiconductor device using the same. These example embodiments relate to a method of manufacturing a semiconductor device including a pad for electrically connecting a capacitor or a bit line to a source/drain region of a semiconductor substrate.

Method of Forming a Layer

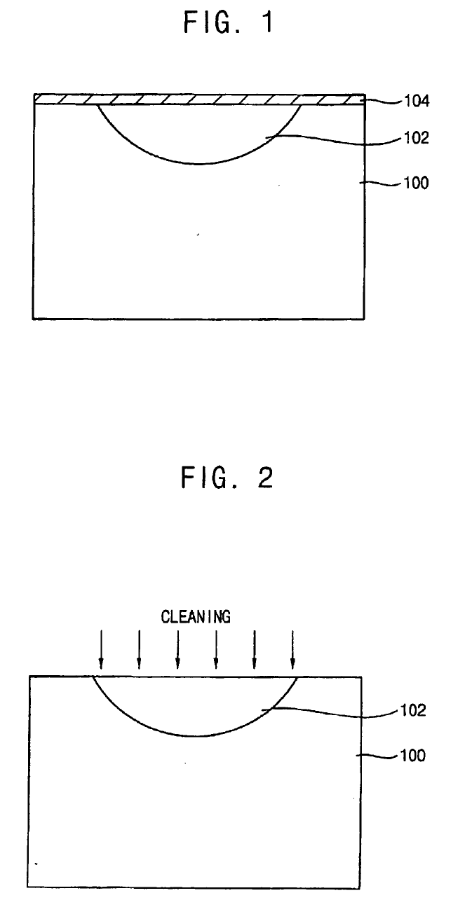

FIGS. 1 to 4 are cross-sectional views illustrating a method of forming a layer in accordance with example embodiments of the present invention.

Referring to FIG. 1, an impurity region 102 may be formed at an upper portion of a semiconductor substrate 100. In forming a positive-channel metal oxide semiconductor (PMOS) device on the semiconductor substrate 100, a single crystalline silicon substrate including N-type impurities may be used as the semiconductor substrate 100. For example, the N-type impurities may include phosphorus (P), and the semiconductor substrate 100 may be a single crystalline silicon germanium substrate doped with phosphorus. In forming a negative-channel metal oxide semiconductor (NMOS) device on the semiconductor substrate 100, a single crystalline silicon substrate including P-type impurities may be used as the semiconductor substrate 100. For example, the P-type impurities may include boron (B), and the semiconductor substrate 100 may be a single crystalline silicon germanium substrate doped with boron. Hereinafter, a method of forming a layer when the NMOS device is formed on the semiconductor substrate 100 will be described.

Doping the semiconductor substrate 100 with impurities may be performed by an ion implantation process or a diffusion process. For example, in the ion implantation process, after ionizing and sequentially accelerating impurities, the impurities having higher kinetic energies may be compulsorily implanted into an upper portion of the semiconductor substrate 100. While performing the ion implantation process, movements of particles in a lateral direction may hardly occur such that the ion implantation process advantageously enhances an integration degree of a cell. However, the ionized impurities may severely damage a lattice structure of the semiconductor substrate 100 in the ion implantation process. The damaged semiconductor substrate 100 may be recovered by a heat treatment process.

Impurities may be implanted into an upper portion of the semiconductor substrate 100 using thermal energy in the diffusion process. The diffusion process may be performed at a temperature of about 800° C. to about 1200° C. The diffusion process may generally include a deposition, a formation of a capping oxide layer, and a drive-in diffusion. An oxide layer including impurities may be formed on the semiconductor substrate 100 in the deposition step. The oxide layer may be divided into a silicon oxide layer and an impurity layer while forming the capping oxide layer such that the silicon oxide layer may function as the capping oxide layer. That is, the silicon oxide layer may prevent leakage of the impurities from the impurity layer. The drive-in deposition may enable the impurity layer to obtain a desired depth by controlling temperature and time.

In an example embodiment of the present invention, the semiconductor substrate 100 may be doped with phosphorus (P) by the ion implantation process or the diffusion process to form the impurity region 102 doped with phosphorus at an upper portion of the semiconductor substrate 100. When the semiconductor substrate 100 includes single crystalline silicon, silicon may be easily reacted with oxygen in an air to form a native oxide layer 104 on the semiconductor substrate 100. The native oxide layer 104 may disadvantageously increase a resistance of a conductive layer that is subsequently formed.

Referring to FIG. 2, a cleaning process may be performed on the semiconductor substrate 100 to remove the native oxide layer 104 from the semiconductor substrate 100.

A wet cleaning process using hydrogen fluoride (HF) or a dry cleaning process using hydrogen (H₂) gas may be the cleaning process. After performing the cleaning process, a hydrogen atom (H) may be weakly adsorbed to the surface of the semiconductor substrate 100. The hydrogen atom may effectively prevent silicon of the semiconductor substrate 100 from being re-oxidized by oxygen gas in the air.

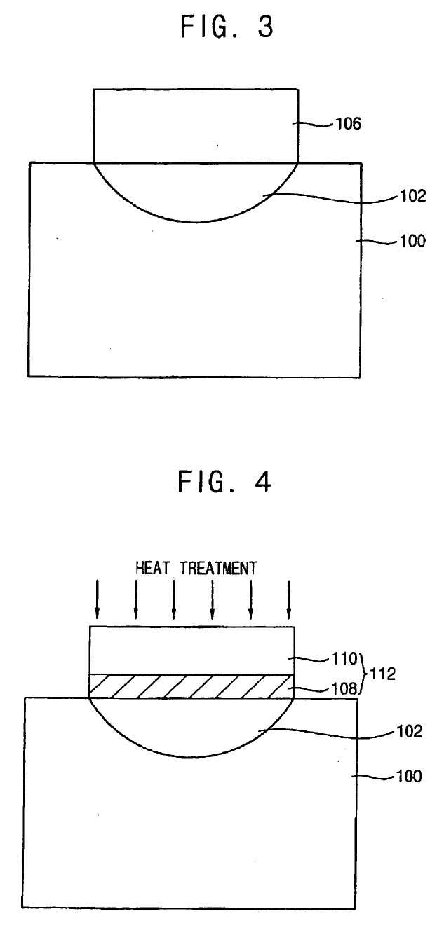

Referring to FIG. 3, a first layer 106 may be formed on the impurity region 102. The first layer 106 may be formed using amorphous silicon doped with impurities. An example of the impurities may include phosphorus, which may be substantially the same material as the impurities included in the impurity region 102.

The first layer 106 may be formed by depositing amorphous silicon through a low pressure chemical vapor deposition (LPCVD) process using silane (SiH₄) gas. While amorphous silicon is depositing, the first layer 106 may be simultaneously doped with phosphorus using phosphine (PH₃). The first layer 106 may be doped with phosphorus by an ion implantation process, a diffusion process, in-situ doping process, or another similar process.

A vertical furnace may be used as a process chamber for performing the LPCVD process. While the first layer 106 is forming, an internal temperature of the vertical furnace may increase to about 500° C. The hydrogen (H) atom weakly adsorbed onto the semiconductor substrate 100 may be detached from the semiconductor substrate 100, and silicon included the semiconductor substrate 100 may be re-oxidized by oxygen (O₂) gas remaining in the vertical furnace.

In order to prevent re-oxidization of the semiconductor substrate 100, removing the oxygen (O₂) gas from the vertical furnace may be required before performing the LPCVD process. Removing the oxygen (O₂) gas from the vertical furnace may be performed as follows.

The vertical furnace may be evacuated at a lower internal temperature of about 350° C. The hydrogen (H) atom weakly adsorbed onto the semiconductor substrate 100 may easily be detached from the semiconductor substrate 100 at an internal temperature above about 400° C., and the detached portion of the semiconductor substrate 100 may be easily oxidized by the oxygen (O₂) gas remaining in the vertical furnace. In addition, the oxygen (O₂) gas may be very easily combined with silicon of the semiconductor substrate 100 as the internal temperature of the vertical furnace increases. Thus, evacuating the vertical furnace may be advantageously performed at a temperature of about 350° C. A small amount of silane (SiH₄) gas may be introduced into the vertical furnace. The internal temperature of the vertical furnace may be gradually increased from about 350° C. to about 530° C. Accordingly, amorphous silicon may not be deposited while the internal temperature of the vertical furnace is increased. Thus, the first layer 106 may not be formed on the semiconductor substrate 100 and the silane (SiH₄) gas may be still left in the vertical furnace. In addition, a partial pressure of the oxygen (O₂) gas in the vertical furnace may decrease.

After removing the oxygen (O₂) gas from the vertical furnace, the internal temperature of the vertical furnace may be increased up to a range of about 530° C. to about 550° C, and then silane (SiH₄) gas may be introduced into the vertical furnace as a reactive gas for forming the first layer 106. As a result, the first layer 106 including amorphous silicon doped with impurities may be formed on the semiconductor substrate 100.

Referring to FIG. 4, a heat treatment process may be performed at a temperature of about 550° C. to about 600° C. on the semiconductor substrate 100 on which the first layer 106 including amorphous silicon doped with the impurities is formed. Thus, the first layer 106 may be transformed into a second layer 112. The second layer 112 may include a single crystalline silicon thin film 108 doped with impurities formed on the impurity region 102, and a polysilicon thin film 110 doped with impurities formed on the single crystalline silicon thin film 108. Because the heat treatment process may be performed at a temperature below about 600° C., degradations and/or damages to semiconductor devices may be reduced.

When the heat treatment process is performed on the semiconductor substrate 100 having the first layer 106, a lower portion of the first layer 106 making contact with the impurity region 102 may be converted into the single crystalline silicon thin film 108 doped with the impurities by a solid phase epitaxial (SPE) growth using single crystalline silicon of the semiconductor substrate 100 as a seed. Simultaneously, an upper portion of the first layer 106 may be converted into the polysilicon thin film 110 doped with the impurities. The heat treatment process on the semiconductor substrate 100 may be performed under a nitrogen gas atmosphere.

Therefore, the first layer 106 including amorphous silicon having a higher electrical resistance may be converted into a second layer 112 including the single crystalline silicon thin film 108 and the polysilicon thin film 110, each of which has a lower electrical resistance, while the first layer 106 is thermally treated at a temperature of about 600° C. In addition, both the single crystalline silicon thin film 108 and the polysilicon thin film 110 may be originated from the first layer 106 doped with impurities so that the second layer 112 may have a sufficient concentration of impurities to let an electric current flow.

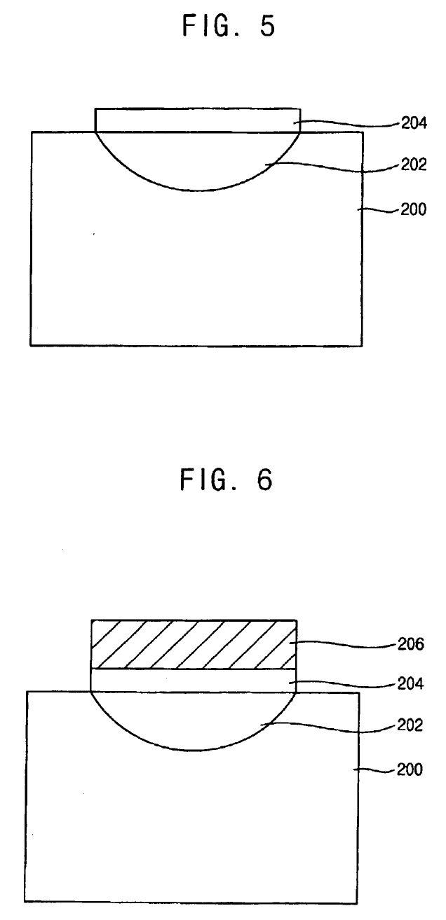

FIGS. 5 to 7 are cross-sectional views illustrating a method of forming a layer according to other example embodiments of the present invention.

Referring to FIG. 5, an impurity region 202 doped with impurities may be formed at an upper portion of a semiconductor substrate 200 and a native oxide layer (not shown) may be removed from the impurity region 202 by a cleaning process as previously described with reference to FIGS. 1 and 2.

A first layer 204 may be formed on the impurity region 202 of the semiconductor substrate 200. The first layer 204 may be formed using a first amorphous silicon undoped with impurities. For example, the first layer 204 may be formed by a LPCVD process using silane gas as a reactive gas at a temperature of about 530° C. to about 550° C.

In an example embodiment of the present invention, remaining oxygen gas may be removed from a chamber for performing the LPCVD process before forming the first layer 204 as previously described with reference to FIG. 3.

Referring to FIG. 6, a second layer 206 may be formed on the first layer 204 using a second amorphous silicon doped with impurities. The impurities doping the second layer 206 may be substantially the same as the impurities included in the impurity region 202. In an example embodiment of the present invention, the first and the second layers 204 and 206 may be formed by an in-situ process using substantially the same chamber.

In another example embodiment of the present invention, a preliminary second layer undoped with impurities may be formed on the first layer 204 using silane gas. While forming the preliminary second layer, the preliminary second layer may be doped with phosphorus (P) using phosphine (PH₃) gas. As a result, the second layer 206 including amorphous silicon doped with phosphorus may be formed on the first layer 204.

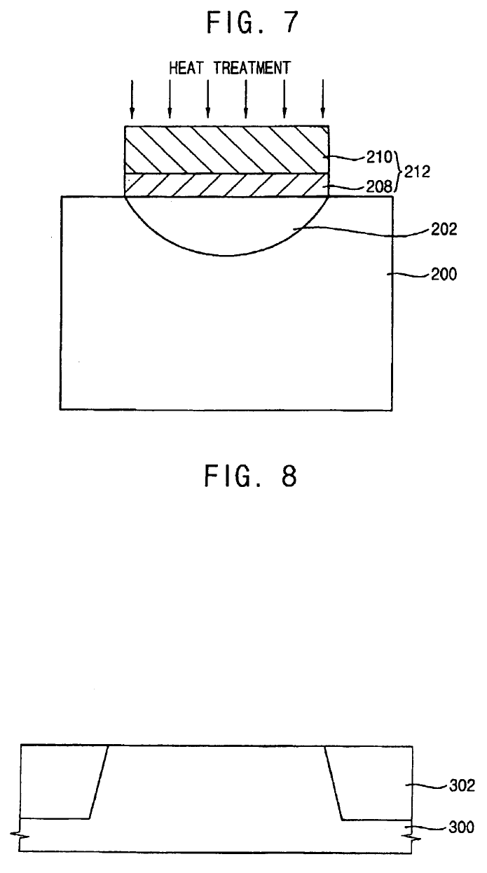

Referring to FIG. 7, a heat treatment process may be performed on the semiconductor substrate 200, including the first layer 204 and the second layer 206, to form a third layer 212. The heat treatment process may be performed at a temperature of about 550° C. to about 600° C. The third layer 212 may include a single crystalline silicon thin film 208 doped with impurities formed on the impurity region 202, and a polysilicon thin film 210 doped with impurities formed on the single crystalline silicon thin film 208.

The first layer 204 including the first amorphous silicon undoped with impurities, which contacts the semiconductor substrate 200, may be converted into the single crystalline silicon thin film 208 by a SPE growth process using single crystalline silicon included in the semiconductor substrate 200 as a seed. Simultaneously, the second layer 206 including the second amorphous silicon doped with impurities may be converted into the polysilicon thin film 210 doped with impurities.

While the first layer 204 is being converted into the single crystalline second thin film 208, the single crystalline silicon thin film 208 may be doped with impurities by diffusion. For example, the single crystalline silicon thin film 208 may be partially doped with impurities that are diffused from the impurity region 202 of the semiconductor substrate 200, and also doped with impurities that are diffused from the second layer 206. Thus, the first layer 204 including the first amorphous silicon undoped impurities may be converted into the single crystalline silicon thin film 208 doped with impurities.

Method of Manufacturing a Semiconductor Device

Hereinafter, a method of manufacturing a semiconductor device using the above-mentioned method of forming the layer will be fully described.

FIGS. 8 to 14 are cross-sectional views illustrating a method of manufacturing a semiconductor device in accordance with example embodiments of the present invention.

A PMOS device and/or an NMOS device may be manufactured on a semiconductor substrate 300. A method of manufacturing an NMOS device will be described as an example hereinafter. A single crystalline silicon substrate 300 including P-type impurities may be used as the semiconductor substrate 300. An example of the P-type impurities may include boron (B). For example, a P-type single crystalline silicon germanium substrate 300 may be used as the semiconductor substrate 300.

Referring to FIG. 8, an isolation layer 302 may be formed at an upper portion of the semiconductor substrate 300 by an isolation process to define an active region and a field region of the semiconductor substrate 300.

After sequentially forming a pad oxide layer (not shown), a silicon nitride layer (not shown) for masking and a photoresist pattern (not shown) on the semiconductor substrate 300, the silicon nitride layer and the pad oxide layer may be partially etched to thereby form a hard mask pattern (not shown) using the photoresist pattern as an etching mask. In an example embodiment of the present invention, an organic anti-reflective layer (ARL) (not shown) may be additionally formed on the silicon nitride layer. The organic ARL may prevent a diffuse reflection in a photo process for forming the photoresist pattern so that the photoresist pattern having a good sidewall profile may be formed. The organic ARL may be formed using silicon oxynitride (SiON). After the hard mask pattern is formed, the photoresist pattern may be removed by an ashing process and/or a stripping process.

The semiconductor substrate 300 may be partially etched using the hard mask pattern as an etching mask to form a trench at an upper portion of the semiconductor substrate 300. In an example embodiment of the present invention, a thermal oxide layer (not shown) and an insulation liner (not shown) may be formed in the trench. A surface of the trench may be thermally oxidized to form the thermal oxide layer having a very thin thickness in the trench. The thermal oxide layer may cure damages to the surface of the trench generated in a dry etching process for forming the trench. The insulation liner may be formed on a bottom and a sidewall of the trench, where the thermal oxide layer is formed, and on the hard mask pattern. For example, the insulation liner may have a thin thickness of about several hundreds of angstroms. The insulation liner may reduce a stress of a silicon oxide layer filling up the trench in a subsequent process and prevent impurity ions of the active region from permeating into the filed region. The insulation liner may be advantageously formed using a material having a higher etching selectivity relative to the silicon oxide layer under a desired etching condition. For example, the insulation liner may be formed using silicon nitride.

A field insulation layer may be formed on the semiconductor substrate 300 to fill up the trench. The field insulation layer may be formed using an oxide specialized in filling up the gaps. Examples of the oxide may include undoped silicate glass (USG), tetraethyl orthosilicate (TEOS) USG together with ozone (O₃-TEOS USG), high density plasma-chemical vapor deposition (HDP-CVD) oxide and the like. The field insulation layer may be formed by a chemical vapor deposition (CVD) process. In an example embodiment of the present invention, the field insulation layer may be advantageously formed using HDP-CVD oxide. Silane (SiH₄) gas, oxygen (O₂) gas and argon (Ar) gas may be used as a plasma source. Deposition conditions may be properly adjusted to enhance the gap-filling characteristics of the HDP-CVD oxide so that generation of cracks and/or voids in the field insulation layer may be prevented or reduced.

In an example embodiment of the present invention, the field insulation layer may be densified by an annealing process. The annealing process may be performed at a higher temperature of about 800° C. to about 1050° C. under an inactive gas atmosphere. Thus, a wet etching rate of the field insulation layer may be reduced in a cleaning process subsequently performed.

An upper portion of the field insulation layer may be removed until the hard mask pattern is exposed. The field insulation layer may be polished by an etch back process and/or a chemical mechanical polishing (CMP) process. As a result, the isolation layer 302 may be formed to fill up the trench, and the semiconductor substrate 300 may be divided into the active region and the field region.

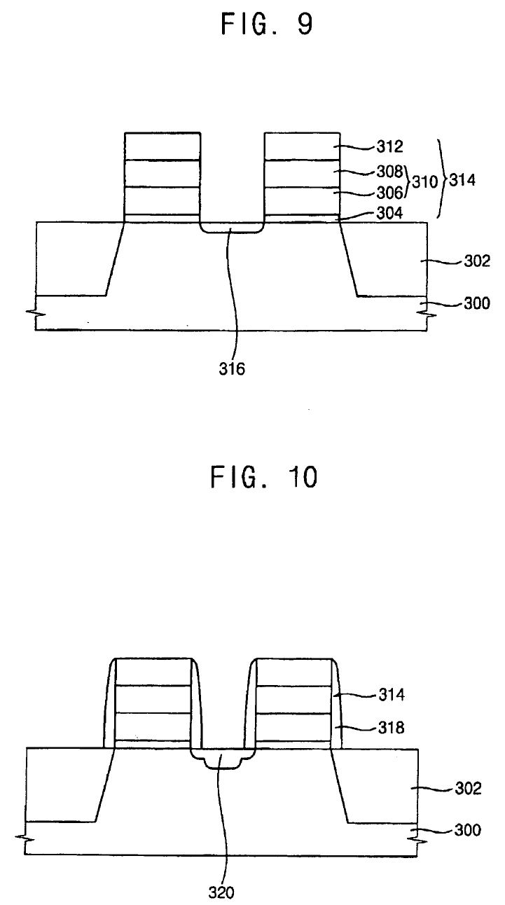

Referring to FIG. 9, after forming a gate oxide layer, a conductive layer and a mask layer may be sequentially formed on the semiconductor substrate 300. The mask layer, the conductive layer and the gate oxide layer may be partially removed to form a gate pattern 314 including a gate oxide layer pattern 304, a conductive layer pattern 310 and a mask pattern 312 on the active region of the semiconductor substrate 300.

After forming the gate oxide layer on the semiconductor substrate 300, the conductive layer used as a gate electrode may be formed on the gate oxide layer.

The conductive layer may have a multi-layered structure that includes a polysilicon layer and a metal-containing layer formed on the polysilicon layer. For example, the polysilicon layer may be doped with impurities in a relatively high concentration by a doping process, for example, a diffusion process, an ion implantation process, an in-situ doping process, etc. The metal-containing layer may be formed on the polysilicon layer using a metal-containing material, for example, tungsten, titanium, tungsten silicide or titanium nitride. Thus, the conductive layer including the polysilicon layer and the metal-containing layer may be formed on the gate oxide layer.

The mask layer may be formed on the conductive layer and may be formed using silicon nitride. The mask layer may be used as a hard mask layer in an etching process subsequently performed. In addition, the mask layer may effectively protect the conductive layer and prevent the conductive layer from being exposed in subsequent processes.

The mask layer, the conductive layer and the gate oxide layer may be partially etched from the semiconductor substrate 300 to form a gate pattern 314 including the gate oxide layer pattern 304, the conductive layer pattern 310 and the mask pattern 312 on the active region of the semiconductor substrate 300.

Impurities may be implanted into an exposed portion of the semiconductor substrate 300 using the gate pattern 314 as a mask. Thus, a preliminary source/drain region 316 may be formed at an upper portion of the semiconductor substrate 300 adjacent to the gate pattern 314. The preliminary source/drain region 316 may be formed by an ion implantation process or a diffusion process. Examples of the impurities may include elements in Group V of the periodic table, for example, phosphorus (P).

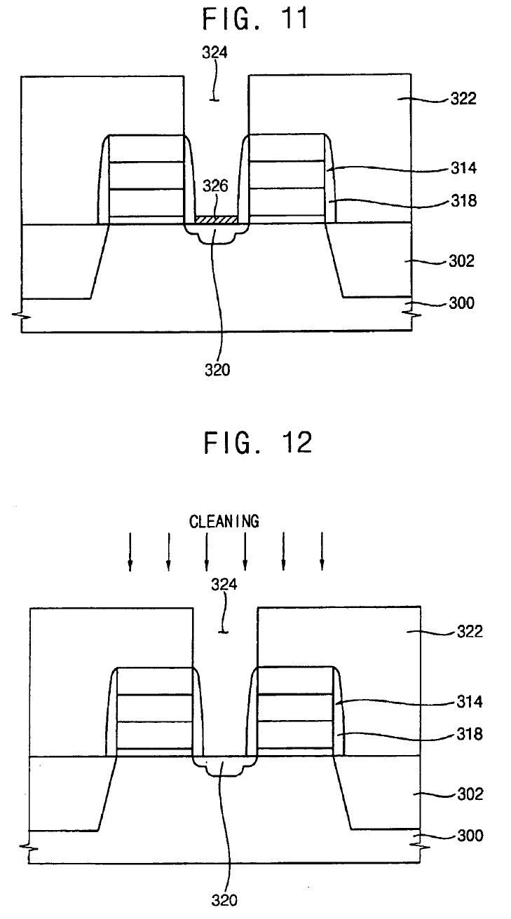

Referring to FIG. 10, after forming a silicon nitride layer on the gate pattern 314 and the exposed portion of the semiconductor substrate 300, the silicon nitride layer may be anisotropically etched from the semiconductor substrate 300 to form a spacer 318 on a sidewall of the gate pattern 314.

Impurities may be implanted into the preliminary source/drain region 316 using the gate pattern 314 and the spacer 318 as masks to form a source/drain region 320. The source/drain region 320 may have a lightly doped drain (LDD) structure that includes a lightly doped region and a heavily doped region.

Thus, a transistor including the gate pattern 314 and the source/drain region 320 may be formed on the active region of the semiconductor substrate 300. The source/drain region 320 may be used as either a capacitor contact region connected to a lower electrode of a capacitor, or a bit line contact region connected to a bit line.

Referring to FIG. 11, an insulating interlayer 322 may be formed on the semiconductor substrate 300, having the source/drain region 320, to cover the gate pattern 314. The insulating interlayer 322 may be formed using an oxide specialized in filling up the gaps. Examples of the oxide may include borophosphosilicate glass (BPSG), undoped silicate glass (USG), spin on glass (SOG) and other similar oxides. In an example embodiment of the present invention, the insulating interlayer 322 may have a multi-layered structure including a first insulation layer and a second insulation layer formed on the first insulation layer. The first insulation layer may be formed using an oxide specialized in filling up the gaps, and then polished by an etch back process and/or a CMP process. The second insulation layer may be formed using an oxide substantially the same as that of the first insulation layer. Alternatively, the second insulation layer may be formed using a material substantially different from that of the first insulation layer.

The insulating interlayer 322 may be partially etched from the semiconductor substrate 300 to form an opening 324 exposing the source/drain region 320. The opening 324 may be formed by a self-aligned contact (SAC) process. For example, a photoresist pattern (not shown) may be formed on the insulating interlayer 322 to expose the source/drain region 320. The insulating interlayer 322 may be anisotropically etched from the semiconductor substrate 300 using the photoresist pattern as an etching mask. The insulating interlayer 322 may be etched using an etching gas having a higher etching selectivity between the insulating interlayer 322 and the spacer 318. For example, the insulating interlayer 322 may be etched using a mixture gas including trifluoromethane (CHF₃), tetrafluoromethane (CF₄) and argon (Ar). The insulating interlayer 322 may be partially etched from the semiconductor substrate 300 using the etching gas to form the opening 324 exposing the source/drain region 320. Although the mask pattern 312 and the spacer 318 may be exposed in the etching process, the mask pattern 312 and the spacer 318 may effectively protect the gate pattern 314 from the etching gas so that a process margin may be enhanced.

Referring to FIG. 12, the source/drain region 320 exposed by the SAC process may be reacted with oxygen gas in an air to form a native oxide layer 326 on the source/drain region 320. The native oxide layer 326 may increase an electrical resistance of a pad subsequently formed on the source/drain region 320, thereby deteriorating reliability of a semiconductor device.

Therefore, the native oxide layer 326 may be advantageously removed by a cleaning process, for example, a wet cleaning process or a dry cleaning process. For example, the wet cleaning process may be performed using hydrogen fluoride (HF) solution, and the dry cleaning process may be performed using hydrogen (H₂) gas. After the cleaning process is performed, hydrogen atoms may be weakly adsorbed onto the source/drain region 320 to prevent re-oxidation of the source/drain region 320.

Referring to FIG. 13, a first layer 328 may be formed on the insulating interlayer 322 to fill up the opening 324. The first layer 328 may be formed using amorphous silicon doped with impurities. The impurities in the first layer 328 may be substantially the same as those of the source/drain region 320. For example, the impurities may include phosphorus.

The first layer 328 may be formed by depositing amorphous silicon and by simultaneously doping impurities, for example, phosphorus. Amorphous silicon may be deposited by a LPCVD process using silane gas, and impurities may be doped into the amorphous silicon by an ion implantation process, a diffusion process or an in-situ doping process using phosphine (PH₃). As a result, the first layer 328 including amorphous silicon doped with impurities may be formed on the insulating interlayer 322 to fill the opening 324.

Before forming the first layer 328, remaining oxygen gas may be additionally removed from a chamber for performing the LPCVD process to prevent the semiconductor substrate 300 from being re-oxidized by the remaining oxygen gas. The chamber may be evacuated at a temperature of about 350° C. to remove oxygen gas from the chamber, and then filled with a small amount of silane gas. The method of removing oxygen gas is previously described with reference to FIG. 3, so any further explanations in this regard will be omitted.

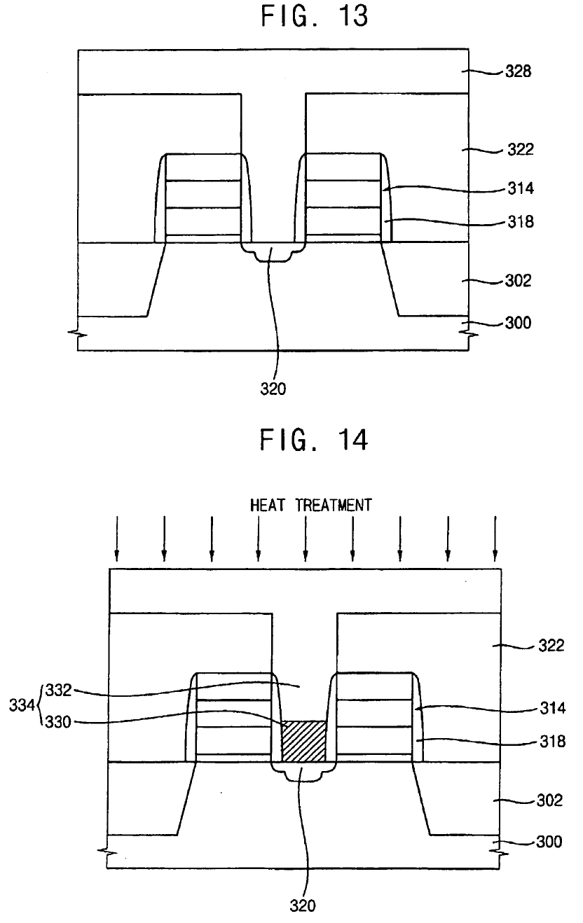

Referring to FIG. 14, a heat treatment process is performed on the semiconductor substrate 300 including the first layer 328. The heat treatment process may be performed at a temperature of about 550° C. to about 600° C. While the heat treatment process is performed, the first layer 328 may be converted into a second layer 334. The second layer 334 may include a single crystalline silicon thin film 330 doped with impurities and a polysilicon thin film 332 doped with impurities. A lower portion of the first layer 328 making contact with the source/drain region 320 may be transformed into the single crystalline silicon thin film 330 by a SPE growth process, and an upper portion of the first layer 328 may be transformed into the polysilicon thin film 332. The heat treatment process may be performed under a nitrogen gas atmosphere.

The first layer 328 including amorphous silicon having a higher electrical resistance may be converted into a second layer 334 including the single crystalline silicon thin film 330 and the polysilicon thin film 332, each of which has a lower electrical resistance. In an example embodiment of the present invention, the heat treatment process may be performed at a temperature of about 550° C. to about 600° C. that is substantially lower than that of a conventional heat treatment process. Thus, damages to a transistor formed on the semiconductor substrate 300 may be prevented in the heat treatment process.

In addition, the second layer 334 may be originated from the first layer 328 including amorphous silicon doped with impurities. The second layer 334 may have a relatively high concentration of impurities and an improved current drive capacity. Thus, the semiconductor device having the second layer 334 may have an enhanced operation speed.

The second layer 334 may be partially removed from the semiconductor substrate 300 until an upper face of the insulating interlayer 322 is exposed. The second layer 334 may be removed by an etch back process and/or a CMP process. As a result, a pad may be formed on the semiconductor substrate 300. The pad may function as either a capacitor contact pad that is electrically connected to a lower electrode of a capacitor, or a bit line contact pad that is electrically connected to a bit line.

In an example embodiment of the present invention, the pad may be electrically connected to a bit line. The bit line may be formed using titanium and titanium silicide. When the pad makes contact with a titanium silicide layer of the bit line, a contact resistance between the pad and the bit line may be reduced, because the pad formed by the SPE growth process may have greatly enhanced electrical characteristics.

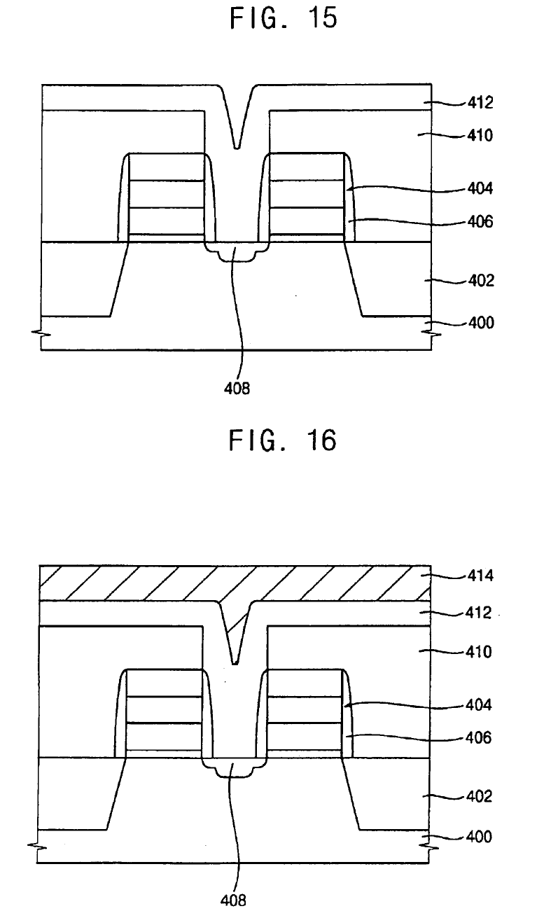

FIGS. 15 to 17 are cross-sectional views illustrating a method of manufacturing a semiconductor device in accordance with other example embodiments of the present invention.

Referring to FIG. 15, a transistor including a gate pattern 404, a spacer 406 and a source/drain region 408 may be formed on a semiconductor substrate 400 as previously described with reference to FIGS. 8 to 10. The spacer 406 may be formed on a sidewall of the gate pattern 404, and the source/drain region 408 may be formed at an upper portion of the semiconductor substrate 400 adjacent to the gate pattern 404. An insulating interlayer 410 may be formed on the semiconductor substrate 400 to cover the transistor, and then partially removed to form an opening exposing the source/drain region 408 as described with reference to FIG. 11. A cleaning process may be performed on the semiconductor substrate 400 to remove a native oxide layer (not shown) formed on the source/drain region 408 as described with reference to FIG. 12.

A first layer 412 including a first amorphous silicon undoped with impurities may be formed on the insulating interlayer 410, the spacer 406 and the source/drain region 408. The first layer 412 may be formed by a LPCVD process using silane gas as a reactive gas.

Referring to FIG. 16, a second layer 414 may be formed on the first layer 412 to fill up the opening. The second layer 414 may be formed using a second amorphous silicon doped with impurities. The impurities in the second layer 414 may be substantially the same as those of the source/drain region 408. For example, the impurities may include phosphorus.

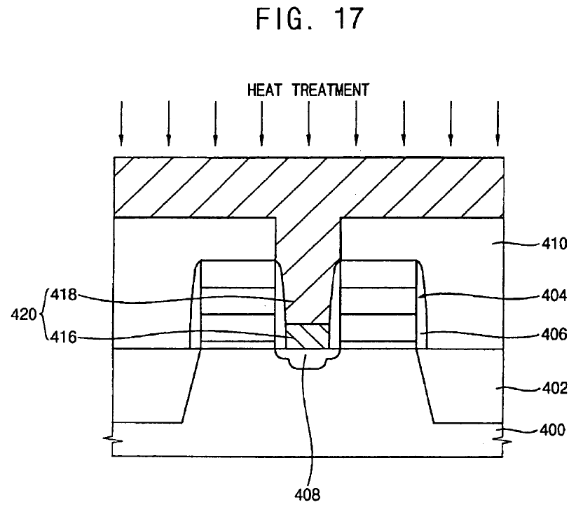

Referring to FIG. 17, a heat treatment process may be performed on the semiconductor substrate 400 having the first and the second layers 412 and 414. The heat treatment process may be performed at a temperature of about 550° C. to about 600° C. under a nitrogen gas atmosphere. While the heat treatment process is performed, the first layer 412 and the second layer 414 may be converted into a third layer 420. The third layer 420 may include a single crystalline silicon thin film 416 doped with impurities and a polysilicon thin film 418 doped with impurities. For example, a lower portion of the first layer 412 making contact with the source/drain region 408 may be converted into the single crystalline silicon thin film 416 doped with impurities by a SPE growth process. Simultaneously, upper portions of the first layer 412 and the second layer 414 may be converted into the polysilicon thin film 418 doped with impurities. Even if the first layer 412 is not doped with impurities, the single crystalline thin film 416 may include impurities that may be diffused from the source/drain region 408 and the second layer 414 in the heat treatment process.

The third layer 420 may be partially removed by an etch back process and/or a CMP process until an upper face of the insulating interlayer 410 is exposed. As a result, a pad may be formed on the semiconductor substrate 400.

According to example embodiments of the present invention, a first layer including amorphous silicon doped/undoped with impurities and a second layer including amorphous silicon doped with impurities may be sequentially formed on a semiconductor substrate, and then a heat treatment process may be performed on the semiconductor substrate so that a portion of the first layer making contact with the semiconductor substrate including single crystalline silicon may be converted into a single crystalline thin film doped with impurities by a SPE growth process and the second layer may be converted into a polysilicon thin film doped with impurities. As a result, a pad including the single crystalline thin film and the polysilicon thin film may be formed on the semiconductor substrate.

Thus, the pad may be formed at a temperature substantially lower than that of a conventional process for forming a pad so that deterioration and/or damage to a transistor formed adjacent to the pad may be prevented or reduced. In addition, because the pad may have an enhanced concentration of impurities, a semiconductor device including the pad may have an improved current drive capacity and an operation speed.

Furthermore, an electrical resistance of a contact region between a bit line and the pad may be reduced, and thus the operation speed of the semiconductor device may be greatly enhanced.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of forming a layer comprising:
forming a first layer on a single crystalline substrate using amorphous silicon doped with impurities; and
performing a heat treatment process on the single crystalline substrate to convert the first layer into a second layer, the second layer including a single crystalline silicon film transformed from a lower portion of the first layer contacting the single crystalline substrate, and a polysilicon film transformed from an upper portion of the first layer.

2. The method of claim 1, wherein the single crystalline substrate has single crystalline silicon or single crystalline silicon germanium.

3. The method of claim 1, wherein the heat treatment process is performed at a temperature of about 550° C. to about 600° C. under a nitrogen gas atmosphere.

4. The method of claim 1, further comprising removing a native oxide layer formed on the single crystalline substrate.

5. The method of claim 1, wherein forming the first layer includes:
forming the lower portion of the first layer on the single crystalline substrate using amorphous silicon undoped with impurities; and
forming the upper portion of the first layer on the lower portion using amorphous silicon doped with impurities.

6. The method of claim 5, wherein the upper and the lower portions of the first layer are formed by an in-situ process using substantially the same chamber.

7. A method of manufacturing a semiconductor device comprising:
forming a gate pattern on a single crystalline substrate;
forming an impurity region at an upper portion of the single crystalline substrate adjacent to the gate pattern;
forming an insulation layer on the single crystalline substrate to cover the gate pattern, the insulation layer including an opening exposing the impurity region; and
forming the layer according to claim 1;
wherein the first layer is a preliminary conductive layer formed on the impurity region to fill up the opening, the second layer is a conductive layer, the single crystalline silicon film is doped with impurities, and the polysilicon film is doped with impurities.

8. The method of claim 7, further comprising removing a native oxide layer from the impurity region by a cleaning process after forming the impurity region.

9. The method of claim 7, further comprising forming a pad on the single crystalline substrate by partially removing the conductive layer until the insulation layer is exposed.

10. A method of manufacturing a semiconductor device comprising:
forming a gate pattern on a single crystalline substrate;
forming an impurity region at an upper portion of the single crystalline substrate adjacent to the gate pattern;
forming an insulation layer on the single crystalline substrate to cover the gate pattern, the insulation layer including an opening exposing the impurity region; and
performing the method of claim 5;
wherein the lower portion of the first layer is a first preliminary conductive layer formed on the impurity region, the upper portion of the first layer is a second preliminary conductive layer and fills up the opening, the second layer is a conductive layer, the single crystalline silicon film is doped with impurities, and the polysilicon film is doped with impurities.
